(19) United States
(12) Patent Application Publication
(10) Pub. No.: US 2002/0112658 A1
(43) Pub. Date: Aug. 22, 2002

(54) Process for monitoring the gaseous environment of a crystal puller for semiconductor growth

(75) Inventors: John D. Holder, Lake St. Louis, MO (US); Shawn K. McGuire, St. Charles, MO (US); Matthew J. Burger, St. Louis, MO (US)

Correspondence Address: SENNIGER POWERS LEAVITT AND ROEDEL, ONE METROPOLITAN SQUARE, 16TH FLOOR, ST LOUIS, MO, 63102, US

(73) Assignee: MEMC Electronic Materials, Inc.

(21) Appl. No.: 10/004,961

(22) Filed: Dec. 3, 2001

Related U.S. Application Data
(60) Provisional application No. 60/257,646, filed on Dec. 22, 2000.

(51) Int. Cl. C30B 15/00; C30B 21/06; C30B 28/10; C30B 30/04

(52) U.S. Cl. 117/15

(57) ABSTRACT

This invention relates to a process for monitoring the gaseous environment within a sealed crystal pulling furnace, used for the growth of an ingot of a semiconductor material in a growth chamber maintained at a sub-atmospheric pressure. The process comprises sealing the chamber, reducing the pressure within the sealed chamber to a sub-atmospheric level, introducing a process gas into the chamber to purge the chamber and form a gaseous environment therein, and analyzing the gaseous environment within the chamber for the presence of a contaminant gas in a concentration which is greater than the concentration of the contaminant gas in the process gas.

### CROSS REFERENCE TO RELATED APPLICATIONS

This application claims priority from U.S. Provisional Application Serial No. 60/257,646, filed on Dec. 22, 2000, which is hereby incorporated herein by reference in its entirety.

### BACKGROUND OF THE INVENTION

The present invention generally relates to the production of a semiconductor grade material. More specifically, the present invention is directed to a process for monitoring the gaseous environment within a crystal puller, such as that employed for single crystal silicon growth, by means of periodic sampling and analysis. Such a process enables the initiation or start-up of the growth process to be more efficiently automated. Additionally, the process enables the early detection of changes in growth process conditions resulting from, for example, a loss of vacuum integrity within the crystal puller or the aging or decomposition of parts within the puller.

Semiconductor material, such as single crystal silicon used for microelectronic circuit fabrication, is typically prepared by the Czochralski (Cz) method. In this process, for example, a single crystal silicon ingot is produced within the crystal growth furnace chamber of a crystal puller by melting a polycrystalline silicon charge in a fused quartz crucible, dipping a seed crystal into the molten silicon, withdrawing the seed crystal to initiate single crystal growth (i.e., forming a neck, crown, shoulder, etc.), and growing the main body of the single crystal under process conditions controlled to maximize the performance characteristics of wafers obtained from the single crystal ingot. In view of the fact that integrated circuit manufacturers continue to place more stringent limitations upon silicon wafers obtained from these ingots, it is of particular importance to minimize those instances wherein, during ingot growth, the conditions within the crystal puller are not within acceptable ranges or limits. Process control is also important because such “out of process” growth conditions can and do lower the quality of the single crystal silicon produced, which in turn decreases process throughput and overall process efficiency and economy.

Czochralski crystal growth is a batch-wise process in that, after producing one or more crystals, it is necessary to discontinue the growth process in order to open the crystal puller, for example, to clean the furnace and replace and/or recharge the crucible. Each time the crystal furnace is opened, many of the vacuum seals are broken, which increases the chance that one or more seals will not adequately engage to prevent leaks when the furnace is closed to begin a new production cycle. In addition to leaks which may occur as a result of opening the crystal puller, the continuously varying thermal conditions within the puller during a growth cycle result in ever-changing stress levels on the crystal growth chamber walls, observation ports and piping connections occasionally, these changing stresses produce conditions that can compromise vacuum seals or create fractures in welds, thus creating additional air, and in some cases water, leaks.

As a result, before a production cycle is begun, it is important to conduct a “pre-fire” vacuum check to determine whether any leaks are present in the crystal puller, or more specifically to determine if any leaks which are out of the ordinary are present, and thus to ensure the vacuum integrity of the crystal growth furnace. A two-step method for testing the vacuum integrity of the crystal growth furnace is commonly employed. The first step involves reducing the pressure within the crystal puller furnace over a set period of time to confirm that the pumping system is working satisfactorily. Then, in the second step, the furnace is isolated from the vacuum pumping system to measure how well the furnace holds the vacuum and to determine whether any leaks which are out of the ordinary are present; that is, once the pressure is reduced, the rate at which the vacuum pressure is lost over a period of time (e.g., 10 minutes) is measured to determine if the rate is out of the ordinary, thus signaling the presence of an atypical leak. Although this practice can identify a leak, the procedure requires a significant amount of time to perform and cannot distinguish the type of leak present or accurately quantify the amount of a suspect leak in the furnace. Furthermore, as the use of large diameter furnaces becomes more prevalent, this practice becomes even less reliable because the large volume of the furnace makes it more difficult to detect small, but significant, leaks. In other words, for large pullers, smaller leaks that can significantly affect the quality of the material being grown are not easily detected because these leaks do not significantly affect the rate at which a large volume furnace loses vacuum pressure.

The presence of leaks in the crystal furnace, which may allow the entry of air and/or water, or water vapor, into the gas stream above or adjacent to the crystal melt, can result in the loss of crystal puller vacuum integrity, which in turn leads to “out of process” conditions or problems during crystal growth. Such “out of process” conditions may also arise during the growth process because of the natural deterioration or aging of the crystal puller parts (e.g., heaters, heat shields, insulation, etc.). Left unchecked, such conditions can significantly reduce the efficient production of an acceptable silicon material. For example, although carbon monoxide is typically present within the crystal puller during crystal growth (formed, for example, by a reaction between the silicon dioxide crucible and the graphite susceptor, or between silicon oxide (SiO) given off from the silicon melt and hot graphite parts in the furnace), elevated carbon monoxide concentrations can result from the presence of air or water vapor within the crystal puller. An elevated carbon monoxide concentration can lead to (i) an elevated carbon level in the crystal that is produced, which is detrimental because this can lead to increased oxygen precipitation in wafers obtained therefrom, and (ii) an increase in the amount of oxide particles formed within the crystal puller, which is detrimental because these oxide particles may accumulate on surfaces within the crystal puller to the extent that flakes may break free and fall into the silicon melt, leading to the loss of dislocation-free growth.

Historically, the loss of vacuum integrity, or the occurrence of “out of process” conditions, has not been reliably monitored or detected during crystal growth.

Although the occurrence of a large air or water leak may be detected during crystal growth if the crystal puller operator observes an increase in the density of an oxide plume from the silicon melt, and/or an increase in the build-up of silicon oxide on hot zone parts within the operator's view, “out of process” conditions affecting crystal growth are typically not detected until after the crystal growth cycle is completed. For example, the presence of a high level of carbon monoxide over the silicon melt surface is typically determined or detected by measuring the amount of carbon in the latter portion of the single crystal silicon ingot. Accordingly, if a problem exists, it is not discovered until after an unacceptable product has been made. In fact, because there can be significant time delays before a defectively-grown ingot is sampled and tested, and the results communicated to the operator of the crystal puller, growth of a second unacceptable ingot can occur. As a result, multiple defective ingots can be grown before an unacceptable process condition is identified, resulting in lost resources, decreased throughput and increased waste.

Accordingly, a need continues to exist for a process by which the gaseous environment within a crystal puller can be more efficiently monitored. More specifically, a need exists for the means by which to more efficiently (i) conduct pre-fire vacuum integrity tests and (ii) detect atypical changes in the vacuum integrity and/or the growth conditions within the crystal growth chamber during the crystal growth process. Preferably, such a process would provide for the automatic start-up of ingot growth if conditions (e.g., vacuum integrity) are acceptable for successful crystal growth, and further would provide for the real time notification of the crystal puller operator when an unacceptable growth condition arises. Such an approach would thus enable the crystal growth process to be altered, or aborted, before or during crystal growth, thus limiting waste and increasing throughput or yield.

### SUMMARY OF THE INVENTION

Among the several features of the invention, therefore, may be noted the provision of a process for monitoring the gaseous environment within a crystal puller before and/or during semiconductor growth; the provision of such a process wherein vacuum integrity is monitored by means of sampling and analyzing the gaseous environment within the crystal puller; the provision of such a process wherein an atmosphere over the melt and/or the exhaust from the crystal puller is sampled and analyzed; the provision of such a process wherein the start-up of the crystal growth process is automated; the provision of such a process wherein an atypical leak is detected and characterized (as, for example, an air leak, a water leak or a purge gas leak); the provision of such a process wherein the size and location of an atypical leak are characterized and quantified; the provision of such a process wherein real-time feedback of the gaseous atmosphere and/or exhaust are provided to an operator of the crystal puller; the provision of such a process wherein elevated levels of carbon monoxide are indicated during crystal growth; and, the provision of such a process wherein throughput and yield for a given crystal puller are increased.

Briefly, therefore, the present invention is directed to a process for monitoring the gaseous environment within a sealed crystal pulling furnace, used for the growth of an ingot of a semiconductor material in a growth chamber maintained at a sub-atmospheric pressure. The process comprises sealing the chamber, reducing the pressure within the sealed chamber to a sub-atmospheric level, introducing a process gas into the chamber to purge the chamber and form a gaseous environment therein, and analyzing the gaseous environment within the chamber for the presence of a contaminant gas in a concentration which is greater than the concentration of said gas in the process gas.

Further, the present invention is also directed to a system for use in combination with an apparatus for growing a semiconductor ingot, wherein the semiconductor growing apparatus has a growth chamber maintained at a sub-atmospheric pressure and containing a gaseous environment comprising a process purge gas. The system comprises a port for withdrawing a sample of the gaseous environment from the growth chamber; a detector for analyzing the sample for a contaminant gas in a concentration in excess of the concentration of the gas in the process purge gas and generating a signal representative of the detected concentration of the contaminant gas, wherein the detector receives the sample from the growth chamber via a conduit connected to the port; and a control circuit receiving and responsive to the signal generated by the detector for determining if the detected concentration of the contaminant gas exceeds a pre-set threshold concentration for the contaminant gas, wherein the control circuit controls the semiconductor growth apparatus in response to the determination.

Other objects and features of the present invention will be in part apparent and in part pointed out hereinafter.

### BRIEF DESCRIPTION OF THE DRAWINGS

FIG. 1A is a section view of the right side of a Czochralski crystal growth furnace chamber.

FIG. 1B is a section view of the left side of a Czochralski crystal growth furnace chamber.

FIG. 2 is a schematic diagram of one embodiment of a system for quantifying, monitoring and/or controlling growth of a semiconductor material in a Czochralski crystal growth furnace chamber.

FIG. 3 is a graph showing the measured carbon monoxide concentrations for the crystal growth runs A through S, as described further in Example 2.

FIG. 4 is a graph comparing the measured carbon monoxide concentrations within the furnace and exhaust gases for the crystal growth runs A through S, as described further in Example 2.

FIG. 5 is a graph showing the measured carbon concentrations of some of the crystals produced in the crystal growth runs described in Example 2.

FIGS. 6a and 6b are copies of photographs taken of two ingots, grown as described in Example 2, while

FIG. 6c is a copy of a photomicrograph of a segment of the ingot shown in FIG. 6b.

FIG. 7 is a graph showing the measured nitrogen concentrations within the crystal furnace gases during the pre-fire check before crystal growth runs A through P, as described further in Example 3.

FIG. 8 is a graph showing the measured nitrogen concentrations within the crystal furnace exhaust gases during the pre-fire check before crystal growth runs A through P, as described further in Example 3.

FIG. 9 is a graph showing the measured nitrogen concentrations within the crystal furnace gases during the crystal growth runs A through P, as described further in Example 3.

FIG. 10 is a graph showing the measured nitrogen concentrations within the crystal furnace exhaust gases during the crystal growth runs A through P, as described further in Example 3.

### DETAILED DESCRIPTION OF THE PREFERRED EMBODIMENTS

In accordance with the process of the present invention, it has been discovered that the gaseous environment within a crystal puller can be monitored by means of sampling and analyzing that environment to detect: (i) a loss of vacuum integrity, or a change therein, prior to or during the growth of a semiconductor material; and/or (ii) the occurrence of “out of process” growth conditions during the growth of a semiconductor material. More specifically, the present invention monitors the gaseous environment within the growth furnace of a crystal pulling apparatus and/or the exhaust ports of the furnace, in order to identify the presence of one or more contaminant gases at a concentration which is near to, or in excess of, some unacceptable limit. In this way, the presence of leaks, which can lead to changes in the vacuum integrity of the crystal puller before or during the growth process, and/or changes in process conditions during the growth cycle can be detected. Such an approach can provide the crystal puller operator with real time feedback regarding conditions within the crystal puller environment (e.g., the composition of the gaseous atmosphere above the melt surface or of the crystal puller exhaust) prior to and during crystal growth.

The present process thus allows for the start-up of the crystal growth process to be automated, and further enables much earlier detection of changes within the crystal puller environment which can lead to unacceptable growth conditions. This early detection provides the crystal puller operator with the opportunity to abort the growth process or, in some cases, to initiate corrective actions, at a much earlier stage, thus limiting the amount of unacceptable silicon which is grown. Additionally, monitoring the crystal growth environment over time enables repairs and routine maintenance to be scheduled and completed much earlier and before an unacceptable condition arises, therefore effectively preventing unnecessary process downtime. As a result, the present invention increases overall process throughput and yield, and therefore overall process efficiency.

In this regard it is to be noted that, as used herein, the phrase “vacuum integrity” refers to the ability of the crystal puller to substantially maintain a typical vacuum pressure prior to and during crystal growth. Stated another way, a crystal puller having “vacuum integrity” is substantially free of atypical leaks in the vacuum seals present therein, leaks which would otherwise result in an increase in the concentration of contaminant gases, from the atmosphere outside the crystal puller, beyond acceptable levels (as further described herein). While the “typical” vacuum integrity, or vacuum pressure, may vary from one crystal puller to the next, this is routinely determined by means common in the art, such as by statistical process control (“SPC”), as further described herein below.

It is to be further noted that, as used herein, the term “out of process” refers to a process condition that is atypical, unexpected, or out of the ordinary. Again, while such conditions may vary from one crystal puller or crystal pulling process to another, “in process” conditions are routinely determined by means common in the art, such as by statistical process control. Examples of such “out of process” conditions include when an upper or lower control limit, as established by SPC, is exceeded, or when a process condition, over a statistically significant number of monitoring cycles, appears to be trending away from what is typical.

It is to be still further noted that, as used herein, “real time” is intended to refer to a process wherein sampling, analysis, and the reporting of results occur essentially instantaneously; that is, there is essentially no delay in the time (i.e., less than about 1 second, 0.5 seconds, or even 0.2 seconds) over which samples are collected, analyzed and reported to the operator. As a result, there is essentially no difference between the gaseous environment within the puller at the time the samples are collected and at the time the results are reported.

System Design Overview

The present invention will be described within the context of an exemplary crystal pulling apparatus suitable for the growth of semiconductor material. More specifically, the present invention will be generally described within the context of a Czochralski-type crystal growth furnace, such as that commercially available from Kayex of Rochester, N.Y., designed for the growth of a 300 mm nominal diameter single crystal silicon ingot. However, in this regard, it is to be noted that the invention may likewise be used with any Czochralski-type furnace design suitable for the growth of various diameters (e.g., nominal diameters of 150 mm, 200 mm and 300 mm or more) of silicon and other such semiconductor materials, such as compound semiconductors (e.g., GaAs).

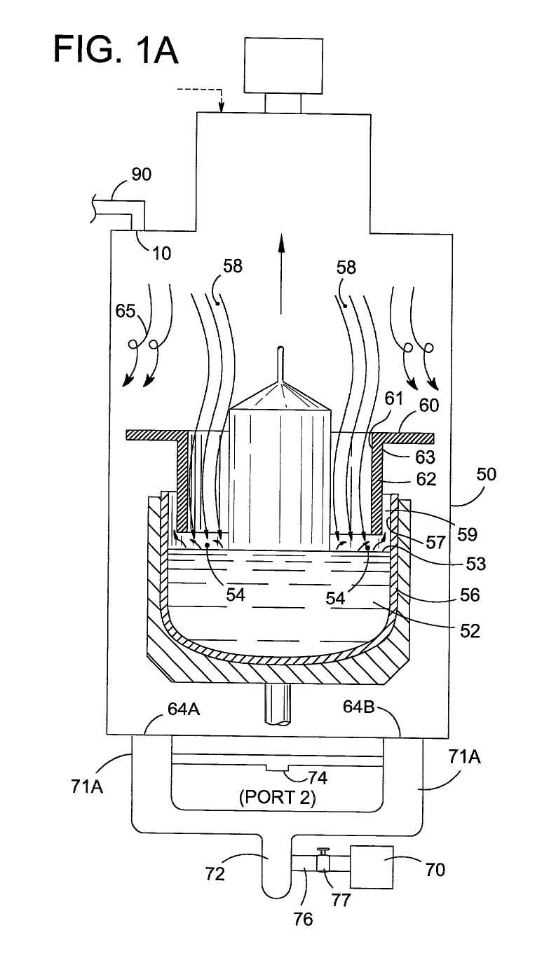

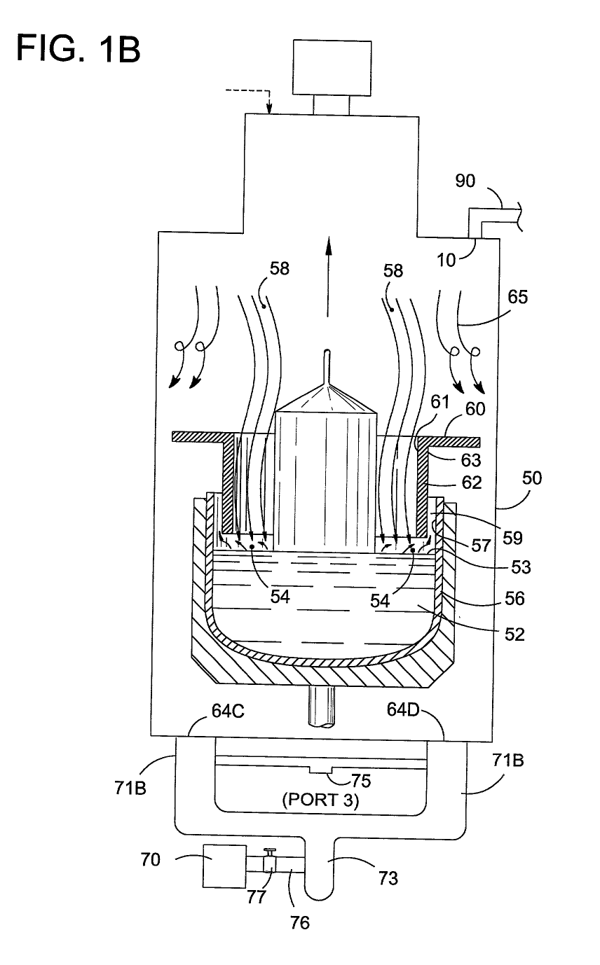

Referring now to FIGS. 1A and 1B, the crystal growth furnace, sealed with the crystal pulling apparatus, comprises a pulling chamber 50 having a device (not shown) for lifting and rotating a growing crystal 55, a growth chamber 51 wherein the polysilicon charge is melted in a silica crucible 56 supported by a graphite susceptor 57 and heated by an electrical resistance graphite heater (not shown). The furnace further comprises a purge tube 60 wherein an inert purge gas 58, such as argon, preferably flows down the center of the crystal puller 50, over the growing silicon ingot 55 and is predominantly peripherally constrained by the inner surface 61 of the vertical wall 62 of the purge tube 60. The purge gas 58 mixes with SiO over the melt surface 53 and the gas mixture flows peripherally outward and then upward through an annular region 59 defined by the outside surface 63 of the purge tube vertical wall 62 and the inner wall surface 57 of the crucible 56. The gas mixture exiting the annular region 59 as well as purge gas 58 that was not constrained by the purge tube 60 is removed from the crystal puller 50 via four exhaust outlets 64a, 64b, 64c and 64d arranged so as to be equidistant along the periphery of the base of the growth chamber. The exhaust outlets 64a through 64d are in fluid communication with a vacuum pumping system 70 by a vacuum piping system comprising two pairs of vacuum pipes 71a and 71b. Each pair of vacuum pipes is attached to two of the exhaust outlets 64a through 64d and extend into the growth chamber 51 by graphite extensions lined with silica glass tubes (not shown). Each pair of vacuum pipes 71a and 71b are reduced into a right-hand side (RHS) pipe 72 and a left-hand side (LHS) pipe 73 respectively. The RHS pipe 72 and LHS pipe 73 are subsequently reduced into a main exhaust pipe 76, which ends into the vacuum pumping system 70. A main exhaust valve 77 is positioned in the main exhaust pipe 76 prior to the vacuum pumping system 70.

In operation, the present process samples the gaseous environment from within the growth furnace, for example, the atmosphere above the melt surface and/or the gases in the exhaust from the crystal pulling furnace chamber, and passes the samples to a detector for characterization and/or quantification. More specifically, in the context of the embodiment shown in FIGS. 1A and 1B, samples of the gas above the melt (referred to herein as Port 1 samples) are collected from one or more sample ports 10 positioned adjacent to the growing crystal 55 within the crystal puller and samples of the gas in the furnace exhaust (referred to herein as Port 2 and Port 3 samples) are collected from sample ports 74 and 75 located within exhaust pipes 71a and 71b respectively.

In this regard it is to be noted that the position of >the sampling ports may be other than herein described. For example, generally speaking, the ports are positioned at locations which enable collection of the most representative samples of gases which the melt surface and growing ingot “encounter.” Additionally, it is to be noted that, although preferred in some embodiments, the sampling and analysis of exhaust gases are optional. Experience to-date indicates sampling in this location can be beneficial, for example, in characterizing the source or cause of “out of process” growth conditions in the growth chamber.

It is to be further noted that, depending on the diameter of the crystal puller and/or other dimensions of the crystal growth furnace, it may be preferable to monitor the gases from within the crystal growth furnace at more than one sample port 10, particularly when gas flow within the chamber is not uniform above the melt. In any case, when positioning sample port(s) 10 within the growth furnace, the sample port(s) is preferably located sufficiently far from the direct flow of purge gas 58 or any known sources of common air leaks (for example, the polysilicon feed tube), such that the collected samples are not diluted or would otherwise not be representative of the gaseous environment adjacent to the growing crystal. In a particularly preferred embodiment, sample port 10 is positioned above the section of the purge tube 60 wherein the flow of purge gas 58 is not constrained within the purge tube 60 as described above. This is preferable, for example, because the flow of purge gas in this region tends to develop eddys 65 which, over time, may further concentrate any contaminant gases which may be present above the crystal melt before such gases can be delivered to the furnace exhaust. Therefore, in this sense, samples collected from this “eddy region” may be more likely to indicate a loss of vacuum integrity or other out of process condition.

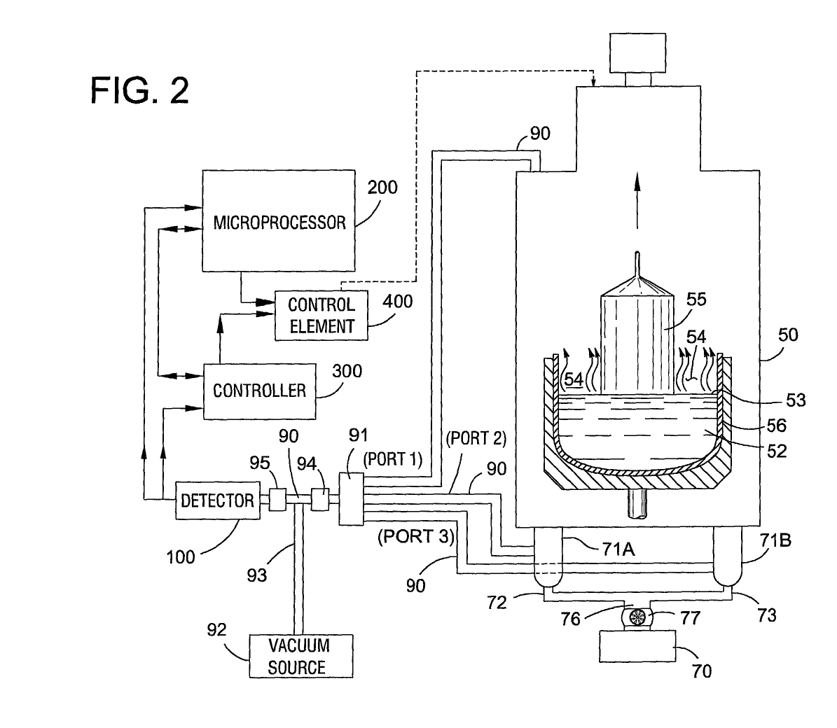

Referring now to FIG. 2, the collected samples are passed from the sample ports (sample port 10, sample port 74 and sample port 75) to the detector 100 through individual conduits 90, which typically comprise one-quarter inch (about 6 mm) diameter flexible stainless steel tubes, which may optionally be wrapped in heating tape (not shown) in order to prevent the condensation of gases. The conduits 90 are in fluid communication with the sample ports 10, 74 and 75 and are adapted for fluid communication with the detector 100. While the sample ports may be directly connected to the detector 100, sample transfer is preferably facilitated by means of a sample transfer device 91 or other means for connecting and switching between multiple sample inlets.

The transfer of gases from the sample ports to the detector 100 may be further facilitated by means of a vacuum pump 92 having a suction line 93 in fluid communication with the conduit 90 or sample transfer device 91. The vacuum pump 92 should preferably be capable of drawing a vacuum of less than about 10 torr (about 1.5 Pa). The suction line 93 can draw from conduit 90 or sample transfer device 91 to pass a sample to the detector 100. The suction line 93 preferably draws from the sample transfer device 91 between first and second detector sample orifices 94, 95 which regulate the sample flow rate to the detector 100. While a single sample orifice configuration can be used, in some embodiments the double sample orifice configuration depicted in FIG. 2 is a preferred system for pressure reduction and is preferably used in conjunction with a continuous flow sample stream bypass. The pressure between the first and second sample orifices 94, 95 is preferably maintained at about 500 mtorr (about 65 Pa) to provide a sufficient pressure differential to transfer the detector sample from the sample port 10 through the conduit 90 to the detector 100. An orifice size of about 1 μm can be used in the second sample orifice 95. The size of the first sample orifice is not narrowly critical, but preferably ranges from about 10 μm to about 5 mm. The sample system is preferably regulated to obtain a constant mass flow rate of gas through the sample port 10 and a constant pressure between the sample orifices 94, 95. Under such conditions, the detector sample enters the detector 100 with a constant volumetric flow rate.

Generally speaking, the sampling system is designed to allow for sampling of the furnace and exhaust gases at temperatures and pressures common for Cz-types of single crystal silicon growth processes, by means of commercially available atmospheric sampling valves. Typically, however, the pressure within the crystal puller during sample collection ranges from about 2 to about 50 torr, from about 5 to about 40 torr, or even from about 10 to about 30 torr, while the temperature ranges from about ambient temperature to about 1400° C. (or more, given that “hot spots” within the growth chamber can occur in some areas, at times reaching 1500° C., 1600° C., or even 1700° C.). More specifically, suitable detectors 100 for monitoring the composition of the gaseous atmosphere above the melt or the exhaust gases from the crystal growth chamber, and/or quantifying the amount of a particular gas therein, include commercially available mass analyzers and gas chromatographic detectors, with mass analyzers being preferred in some embodiments. A particularly preferred detector is a closed (or enclosed) ion source quadrupole gas mass analyzer, having a mass range of about 1 to about 100 amu and a minimum detectable partial pressure of about 5×10⁻¹⁴ torr (using an electron multiplier detector). Such a gas mass analyzer typically operates at pressures ranging from about 1×10⁻⁴ torr (1.3×10⁻² Pa) to about 1×10⁻² torr (1.3 Pa) in their ionizing section, and at pressures ranging from about 1×10⁻⁶ torr (1.3×10⁻⁴ Pa) to about 1×10⁻⁴ torr (1.3×10⁻² Pa) in their detecting section. An example of a suitable detector is a residual gas analyzer (RGA) such as a Qualitorr Orion Quadrupole Gas Mass Analyzer System (available from MKS, UTI Division of Walpole, Mass.). The detector is preferably adapted to detect and quantify the amount of a contaminant gas (e.g., nitrogen, oxygen, water vapor, carbon monoxide) within the collected sample, and thus within the gaseous environment from which the sample was obtained. Additionally, a process purge gas (e.g., argon) is sampled, particularly as a standard to quantify the amounts of the other gases present. For example, in a particularly preferred embodiment wherein the detector is a RGA as described above, it is preferred to monitor N₂ at 14 atomic mass units (amu), monitor O₂ at 32 amu, monitor H₂O at 17 amu, monitor CO at 28 amu and monitor Argon by measuring Ar isotope 36 at 36 amu. As used herein, atomic mass units are equivalent to the particular species molecular weight divided by the charge on the molecule, with the charge on the molecule determined by the ionizer in the RGA. The ionizer may also crack or doubly charge the molecules upon entering the RGA. In any case, the amu for each species of interest should be selected so as to reduce any interference between other major species in the furnace and exhaust gases. In this regard, it has been found to preferably monitor for the presence of H₂O at 17 amu rather than 18 amu to reduce any possible interference with doubly-charged Argon 36. Likewise it is important to note the presence of N₂ at 14 amu to determine if CO should be monitored at 28 amu. If N₂ is present at 14 amu, it is important to look for C at 12 amu to detect the presence of CO so as to minimize any interference with N₂ at 28 amu.

The detector 100 communicates with a PLC or PC furnace control system by means common in the art, such as through a system of open and closed switches or through RS232 or RS485 serial ports. The detector can be instructed by the PLC or PC furnace control system to monitor the gases at desired times and locations (as described herein). The detector 100 outputs a detector signal (e.g., electrical current, voltage, etc.) which is physically representative of, corresponds to or can be correlated to the amount of a particular gas in the furnace chamber or furnace exhaust sample. The detector signal output is communicated, directly or indirectly, to the microprocessor 200. The microprocessor 200 may monitor, display, record or further process the detector signal. In the particularly preferred embodiment wherein the detector is an RGA as described above, the detector signal is converted in the microprocessor to equivalent partial pressures or concentrations of the sampled gases, for example, as follows:

N₂ (ppmv)=0.042×I^{14 amu}/I^{36 amu}×1,000,000 ppmv

O₂ (ppmv)=0.0034×I^{32 amu}/I^{36 amu}×1,000,000 ppmv

H₂O (ppmv)=0.01478×I^{17 amu}/I^{36 amu}×1,000,000 ppmv,

CO (ppmv)=0.0034×I^{28 amu}/I^{36 amu}×1,000,000 ppMV

where I^{xx amu} is the current measured by the RGA detector at xx amu.

Preferably, the detector signal is transmitted or otherwise communicated, directly or indirectly (e.g., through a microprocessor 200), to a controller 300. Any standard controller may be employed, including, for example, analog proportional (P), proportional-integral (PI) or proportional-integral-derivative (PID) controllers, digital controllers approximating such analog P, PI or PID controllers, or more sophisticated digital controllers. A digital PID controller is preferred. Such a digital controller 300 can itself comprise a microprocessor, or can comprise a portion of a larger microprocessor 200. The controller 300 may also communicate, directly or indirectly, with a separate microprocessor 200 to provide user input to the controller, data collection, alarm indications, process control tracking, etc. The controller 300 (or microprocessor 200) may modify the received detector signal for use in calculating the changes in process conditions, for user-interface or for data acquisition or display.

The controller 300 generates a control signal based on the detector signal (either as received from the detector 100 or as modified by the microprocessor 200 or controller 300). In a preferred application, the controller converts the detector signal to a control signal by applying a control law based upon the conditions necessary for controlling the automatic start-up of the crystal furnace heater. Generally, this control law may be based on theoretical and/or empirical considerations. The control law used in a particular situation varies depending on the process condition and on the type of process control element being manipulated. The control signal generated by the controller 300 may be of a variety of types (e.g., pneumatic or electrical), and can be transmitted or otherwise communicated, directly or indirectly, to a process control element 400 which changes at least one process condition. A control signal can also be communicated to the process control element 400 via the microprocessor 200 (dashed line in FIG. 2).

In view of the foregoing, the present invention will be discussed hereafter in particular detail in regard to operating protocols associated with conducting an automated pre-fire vacuum integrity test and for general monitoring during crystal growth to detect out of process conditions. It is to be noted, however, that the process of the present invention may be carried out using a system design other than herein described. For example, multiple crystal pullers may be connected to a single RGA monitoring system (e.g., 2, 3, 4 or more).

Pre-Fire Vacuum Integrity Check

In the practice of one embodiment of the present invention, the crystal growth process is begun by loading a crucible, contained within a growth furnace or chamber of a crystal pulling apparatus, with an initial charge of a semiconductor raw material (e.g., chunk and/or granular polysilicon) and attaching a seed crystal to the crystal pulling system. The furnace is then closed and sealed. The furnace control system is instructed to begin the pre-fire vacuum check. The inert purge gas (e.g., argon) inlets are closed and the main exhaust valve is opened and the air is pumped from the furnace. When the pressure has been sufficiently reduced, typically to a pressure of less than about 200 mtorr (e.g., about 190, 170, 150 torr or less), the main exhaust valve is closed, the purge inlet is opened and the furnace is filled with a process purge gas, for example argon (Ar), to a pressure of about 100 torr (e.g., about 75, 85, 95, 105, 115 or about 125 torr). The cycle of reducing the pressure and then back-filling with an inert process gas is repeated about two additional times. After the third cycle, the furnace is back-filled to a pressure ranging from about 2 to about 50 torr (e.g., about 5, 10, 15, 20, 25 torr or more), and the process gas inlets and main exhaust valves are balanced to maintain a flow rate ranging from about 15 to about 100 slm (standard liters per minute or liters per minute adjusted for standard temperature and pressure), typically about 20, 40, 60 or even about 80 slm, through the pull chamber, the growth chamber and the exhaust piping.

Generally speaking, once the growth chamber has been sufficiently purged, the gaseous environment is sampled and analyzed about once every 20 minutes, 15 minutes, 10 minutes, 5 minutes or even every minute. Preferably, however, sampling and analysis will occur on a continuous basis. In a particularly preferred embodiment, this is achieved by automated means. For example, when automated, the furnace control system instructs the detector to monitor the gaseous environment within the crystal puller (e.g., the atmosphere over the silicon melt and/or the crystal puller exhaust) at each port (sequentially or, depending upon the number of detectors and/or the system configuration, simultaneously). If the partial pressure of one or more, and typically if the partial pressure of all, contaminant gases of interest (e.g., N₂, O₂ and/or H₂O) are below an acceptable limit, or alternatively within an acceptable range, the furnace control system allows the heaters in the growth chamber to be energized in order to begin heating/melting the polysilicon charge. Generally speaking, this “pre-fire” check may last a few minutes (e.g., about 2, 4, 8, 10 minutes or more), a few tens of minutes (e.g., about 10, 20, 30, 40 minutes), or more with sample collection and analysis continuing throughout this time frame, or over only a portion thereof.

The sampling and analysis of the gaseous environment will generally continue until it has been determined that it is suitable for crystal growth to be initiated (i.e., for the furnace heater(s) to be “fired”). Based upon experience to-date, it has been found that the furnace heater may typically be started automatically when the gaseous environment within the growth chamber above and/or adjacent to the crucible (Port 1) has a contaminant gas concentration, for example, of less than about 100 ppmv of N₂ (e.g., less than about 80 ppmv, 60 ppmv, 40 ppmv, or even 20 ppmv); less than about 30 ppmv of O₂ (e.g., 25 ppmv, 20 ppmv, 15 ppmv, or even 10 ppmv); and/or, less than about 200 ppmv of H₂O (e.g., 175 ppmv, 150 ppmv, 125 ppmv, or even 100 ppmv). However, in those instances where the concentration of a contaminant gas is in excess of the noted limit (i.e., the automatic starting values), the crystal furnace operator may optionally override the monitoring system and manually start the crystal furnace heater. For example, such actions may be taken when the concentration of N₂ ranges from about 100 to about 600 ppmv (e.g., from about 150 to 550 ppmv, about 200 to about 500 ppmv, or about 250 to 450 ppmv), the concentration of O₂ ranges from about 30 to about 100 ppmv (e.g., from about 40 to 90 ppmv, or about 50 to 80 ppmv), and the concentration of H₂O ranges from about 200 to about 1000 ppmv (e.g., from about 300 to 900 ppmv, about 400 to 800 ppmv, or about 500 to 700 ppmv). For concentrations of N₂ above about 600 ppmv, O₂ above about 100 ppmv, and H₂O above about 1000 ppmv, the furnace control system will typically require restarting the pre-fire vacuum check.

Although optional in some embodiments, when exhaust sampling is employed (e.g., from the RHS pipe (Port 2) and the LHS pipe (Port 3)), the furnace control system will typically start the furnace heater automatically if the concentration of N₂ is less than about 50 ppmv (e.g., less than about 40, 30, or even 20 ppmv), the concentration of O₂ is less than about 10 ppmv (e.g., less than about 8, 6 or even 4 ppmv), and the concentration of H₂O is less than about 200 ppmv (e.g., less than about 175 ppmv, 150 ppmv, 125 ppmv, or even 100 ppmv). For concentrations exceeding these automatic starting values, the crystal furnace operator may override the monitoring system and manually start the crystal furnace heater when the concentration of N₂ ranges from about 50 to about 100 ppmv (e.g., from about 60 to 90 ppmv, or about 70 to 80 ppmv), the concentration of O₂ ranges from about 10 to about 20 ppmv (e.g., from about 12 to 18 ppmv, or about 14 to 16 ppmv), and the concentration of H₂O ranges from about 200 to about 1000 ppmv (e.g., from about 300 to 900 ppmv, about 400 to 800 ppmv, or about 500 to 700 ppmv). For concentrations of N₂ above 100 ppmv, O₂ above 20 ppmv and H₂O above 1000 ppmv, the furnace control system will typically require restarting the pre-fire vacuum check.

In this regard it is to be noted that, in some instances, the initial water concentration (i.e., the water concentration prior to the “firing” of the heaters) may be ignored; that is, in some instances, the growth process may be initiated when the water vapor concentration is in excess of 1000 ppmv. Generally speaking, this is because, in a crystal puller at ambient temperature, a significant amount of water vapor can be present on, for example, the surfaces of the graphite parts. Given that the puller is rapidly heated to a temperature in excess of that which causes water to vaporize, this initial presence of water can be quickly reduced.

It is to be further noted that, in some instances, the vacuum integrity of the crystal puller is monitored by means of analyzing the gaseous environment within the crystal puller for the presence of all of the above-referenced contaminant gases, while in other instances the environment will be analyzed for the presence of only one or two of the gases. Additionally, it is to be noted that the inert process or purge gas employed may contain trace levels of one or more of the contaminant gases, levels which are acceptable for purposes of the present invention. Accordingly, generally speaking, the process of the present invention enables the automated “firing” of the crystal puller when the concentration of nitrogen ranges from about 5 ppmv to less than about 50 ppmv or 100 ppmv (depending upon whether the concentration in the exhaust gas or above/adjacent to the melt surface, respectively, are being considered), when the concentration of oxygen ranges from about 2 ppmv to less than about 10 ppmv or 30 ppmv (again, depending upon whether the concentration in the exhaust gas or above/adjacent to the melt surface, respectively, are being considered), and when the concentration of water ranges from about 2 ppmv to less than about 200 ppmv.

It is to be still further noted that while the concentration levels provided above are generally applicable to semiconductor growth processes, the “critical” levels for initiating growth may be other than described herein without departing from the present invention. Specifically, from one crystal puller or crystal pulling process to another, the unacceptable level of one or more contaminant gases may vary. As a result, it is preferred to employ means common in the art, such as statistical process control, to determine a “baseline” for each process condition or contaminant gas level which is “typical.” Such an approach generally involves conducting a series of pre-fire tests, and optionally a series of complete growth cycles, while monitoring the growth conditions in order to identify typical or ordinary conditions. A “window” of acceptable conditions is then established; that is, some degree of variation (e.g., about 2%, 4%, 6%, 8%, 10%, etc.) is then allowed, beyond which the crystal puller operator is notified that an atypical condition is present. A common approach, for example, is to conduct a series of statistically significant tests to establish a median level for each contaminant gas of interest, and then allow a range of: (i) median plus, or in some cases minus, two times the standard deviation, (ii) median plus, or in some cases minus, three times the standard deviation, or (iii) median plus, or in some cases minus, some multiple of the standard deviation in excess of three (e.g., 4, 5 or more). In this way, the present process may be “tuned” to optimize the pre-fire or growth conditions for any crystal puller or crystal pulling process.

In a preferred embodiment, the concentration of a contaminant gas is determined at multiple locations (e.g., above and/or adjacent to the melt surface and/or in one or more of the exhaust gas ports), before the heaters of the crystal puller are “fired” and meltdown is begun. As discussed further below, sampling in multiple locations is beneficial for a number of reasons. For example, depending upon design of the growth chamber, gas flow through the chamber may not be uniform. As a result, regions having different gas compositions within the chamber may be present. Additionally, the vacuum integrity of the crystal puller may be compromised in a number of different ways, each of which may occur in a localized area, again depending upon the design of the crystal puller/crystal growth chamber. These factors should be kept in mind when optimizing (either by empirical means, or by gas flow models common in the art) sample port placement, the number of sample ports to be employed, sampling frequency, etc.

Monitoring During Crystal Growth

In a second embodiment of the present invention, during the semiconductor growth process (i.e., once meltdown has begun), gases within the growth chamber above and/or adjacent to the silicon melt surface, and/or the gases in the exhaust from the chamber, are periodically sampled and analyzed, in order to monitor the vacuum integrity of the crystal puller, as well as to monitor the growth chamber for the presence of other problems which may develop during the growth process (e.g., failure of a purge gas valve, break or leak in a water jacket, build-up of carbon monoxide resulting from the reaction between silicon oxide with various graphite parts, etc.). The gaseous environment with the growth chamber is sampled and analyzed for the presence of a contaminant gas (e.g., oxygen, nitrogen, water vapor, carbon monoxide) in a concentration in excess of some predetermined limit.

The timing of sample collection (e.g., when sampling begins, ends, duration between each sample taken, the number of samples taken during the process, etc.), as well as the location and number of sampling points, will generally be that which is sufficient to ensure representative data of the crystal puller environment is provided throughout the growth process. More specifically, however, sampling for this phase of the present process typically begins as soon as the heaters have been “fired” and initiation of the meltdown has begun, in order to ensure no leaks are present prior to initiation of the semiconductor growth process. Sampling can continue throughout the entire course of crystal growth (e.g., from initiation of meltdown until the end-cone is detached from the melt, or even longer, such as until cool-down of the puller has occurred). Alternatively, sampling may occur over only a portion of this time frame (e.g., during meltdown, growth of the neck or crown, growth of about 20%, 40%, 60%, 80% or about all of the main body, growth of the end-cone, etc.). Regardless of the time frame over which sampling occurs, during the growth process, sample collection and analysis typically occurs at Port 1, and optionally at Ports 2 and 3, about once every 20 minutes, 15 minutes, 10 minutes, 5 minutes, or every minute, or even on a continuous basis.

In this regard it is to be noted that the timing for sampling may be other than herein described without departing from the scope of the present invention. For example, sample collection/analysis may vary depending upon the growth conditions employed, the type of semiconductor material to be formed, the design of the crystal pull apparatus, etc. Generally speaking, however, the timing for a given puller, process, type, etc. may be optimized empirically, for example, by growing a number of different crystals and varying the point at which sample collection begins and ends, how often samples are taken, the number of samples taken, etc.

Generally speaking, when the presence of a contaminant gas is detected at a concentration in excess of the “background” concentration (i.e., at a concentration in excess of the typical concentration, as described further herein, such as the concentration at which the particular contaminant gas of interest is present in the process or purge gas being used), or alternatively when it is detected at a concentration at or nearing some unacceptable concentration, the growth process can be halted, in order to avoid the growth of a segment of a semiconductor ingot (e.g., single crystal silicon ingot) that is not suitable for use. In such cases, the grown ingot can be further processed without concern of an unacceptable segment being present, as the result of an “out of process” condition or an atypical crystal puller leak. The crystal puller can then be immediately examined to identify the source of the contaminant gas, thus limiting “down time” for the crystal puller.

Additionally, if the “out of process” contaminant level is set sufficiently low, the growth process can be continued while the gas level is monitored until just before a “critical” level is reached, at which point growth must be halted to prevent the formation of an unacceptable material. In such instances, corrective actions may be attempted, (e.g., the source of the leak may be located and repaired) during the growth process. Alternatively, other attempts can be taken to prolong the growth cycle, such as, for example, by increasing the flow of an inert purge gas into the crystal puller and/or thereby increasing the flow of exhaust gas out of the crystal puller. In this way, the concentration of the contaminant gas can be diluted or suppressed for a period of time.

In accordance with the process of the present invention, losses in the vacuum integrity of the crystal growth chamber (such as by leaks), and additionally changes in process conditions (i.e., “out of process” conditions) resulting from other sources (e.g., silicon oxide reacting with graphite parts within the growth chamber), are detected by closely monitoring, and preferably continuously monitoring, the composition of the gaseous environment within the chamber, and/or the composition of the exhaust gases from the chamber. More specifically, as described above, after the crystal puller is sealed, the pressure therein is reduced and the sealed chamber is repeatedly purged with an inert process or purge gas in order to lower the concentration of contaminant gases to below some acceptable level. For example, the system may be purged to lower the concentration of nitrogen to less than about 600 ppmv, 400 ppmv, 200 ppmv, or even 100 ppmv; to lower the concentration of oxygen to less than about 100 ppmv, 90 ppmv, 60 ppmv, or even 30 ppmv; and to lower the concentration of water to less than about 1000 ppmv, 800 ppmv, 600 ppmv, 400 ppmv or even 200 ppmv. Once this has been achieved, and the silicon meltdown and/or ingot growth has begun, the gaseous environment within the crystal puller will be monitored for gas concentrations in excess of these amounts.

In this regard it is to be noted that the inert process or purge gas employed may contain trace levels of one or more of the contaminant gases, levels which are acceptable for purposes of the present invention. Accordingly, generally speaking, the process of the present invention allows for ingot growth to continue when the concentration of nitrogen in the gaseous environment ranges from about 5 ppmv to less than about 600 ppmv (e.g., from about 25 to 400 ppmv, about 50 to 200 ppmv, or even about 75 to 100 ppmv), when the concentration of oxygen ranges from about 2 ppmv to less than about 100 ppmv (e.g., from about 10 to 90 ppmv, about 15 to 60 ppmv, or even about 20 to 30 ppmv), and when the concentration of water vapor ranges from about 2 ppmv to less than about 1000 ppmv (e.g., from about 25 to 800 ppmv, about 50 to 600 ppmv, about 75 to 400 ppmv, or even about 100 to 200 ppmv).

It is to be further noted that, unlike the “pre-fire check,” the gaseous environment is also sampled and analyzed for the presence of carbon monoxide; that is, because carbon monoxide begins to form only after the growth chamber is heated, the concentration of carbon monoxide in the gaseous environment within the crystal puller is a concern only after the “pre-fire check” has been completed. Generally speaking, because carbon monoxide is essentially a by-product of the growth process (e.g., the result of a reaction between the silicon dioxide crucible and the graphite susceptor), the gaseous environment will be monitored for a concentration which is in excess of a “background” concentration, with corrective action being taken or the growth process being halted when concentrations that would result in “carbon doping” of the melt occur. Although the concentration will vary with the location of the sampling port P1 (i.e., the port sampling the atmosphere above or adjacent the melt), the “background” concentration of carbon monoxide typically ranges from a few ppmv (e.g., about 2, 4, 6, 8, 10 ppmv or more) to several ppmv (e.g., about 15, 20, 25, 30 ppmv or more). In contrast, carbon monoxide concentrations below the melt (i.e., in the lower regions of the crystal growth chamber, generally below the crucible) are typically quite higher. Thus, the concentration of carbon monoxide in the exhaust port samples will typically be several tens of ppmv (e.g., about 20, 40, 60, 80, 100 ppmv or more). Just as melt doping can be a concern when the carbon monoxide concentration above the melt is elevated (e.g., at concentrations in excess of about 30 or 40 ppmv), elevated concentrations below the melt (e.g., at concentrations in excess of about 100 or 150 ppmv) can be a strong indication of problems within the pull chamber (such as a water leak below the crucible), even when the concentration above the melt is not out of the ordinary or is below an acceptable limit. Such information is beneficial, for example, in more precisely determining when crystal puller maintenance is needed.

It is to be still further noted that while the concentration levels provided above are generally applicable to semiconductor growth processes, the “critical” levels for the growth process may be other than described herein without departing from the present invention. Specifically, from one crystal puller or crystal pulling process to another, the unacceptable level of one or more contaminant gases may vary. As a result, it is preferred to employ means common in the art, such as statistical process control, to determine a “baseline” for each process condition or contaminant gas level which is “typical.” Such an approach generally involves conducting a series of growth cycles, while monitoring the growth conditions in order to identify typical or ordinary conditions. A “window” of acceptable conditions is then established; that is, some degree of variation (e.g., about 2%, 4%, 6%, 8%, 10%, etc.) is then allowed, beyond which the crystal puller operator is notified that an atypical condition is present. A common approach, for example, is to conduct a series of statistically significant tests to establish a median level for each contaminant gas of interest, and then allow a range of: (i) median plus, or in some cases minus, two times the standard deviation, (ii) median plus, or in some cases minus, three times the standard deviation, or (iii) median plus, or in some cases minus, some multiple of the standard deviation in excess of three. In this way, the present process may be “tuned” to optimize the growth conditions for any crystal puller or crystal pulling process.

Such an approach is advantageous for a number of reasons. For example, the particular gas or gases of concern may vary depending upon, for example, the type of material being grown, the type of crystal puller, the location of the crystal puller, the source or type of process purge gas being employed, etc. Growth conditions can also be a factor. For example, higher growth temperatures tend to cause higher “typical” levels of carbon monoxide in the crystal puller (higher temperatures increase the rate of those reactions which produce it). As a result, a higher process temperature means a higher overall “in process” level of carbon monoxide is acceptable, in comparison to when a lower process temperature is employed.

Identification of the Type and/or Source of Leak

It is to be noted that the process of the present invention is advantageous over methods commonly employed in semiconductor growth processes for a number of reasons. For example, not only does the present invention enable the time for “pre-fire” testing to be reduced, as well as enabling the early detection of contaminant gases in the crystal puller, but it also provides information regarding the nature of the leak or contaminant source within the puller. For example, if only nitrogen is found to be at elevated levels, one might suspect that the purge gas is contaminated, because an air leak would lead to the presence of oxygen, and probably water vapor, as well. Similarly, if only water vapor is detected at elevated levels, one might suspect a water leak, because an air leak would lead to the presence of nitrogen, as well. In this way the present invention may act to further reduce equipment “down time,” because the potential sources of the problem can be prioritized.

Additionally, the location of the port from which samples are collected, as well as the timing of the analysis of those samples, can also be controlled to provide beneficial information. For example, sampling and analyzing the exhaust gases is often preferred in some embodiments because the results, when compared to the results of samples collected above the melt or adjacent to the growing ingot, may help to identify the potential cause of an “out of process” condition or to perform “trouble shooting” to determine if other problems with the puller exist (e.g., problems which do not result in “out of process” conditions). For example, by monitoring the exhaust gases in addition to the gases above the melt or adjacent to the growing ingot,

1. the cause of an elevated carbon monoxide level (as detected by port(s) 2 and/or 3) might be identified as being caused by a bad heater (i.e., a heater having “hot spots” which increase the reaction between SiO in the gaseous environment and carbon from the graphite heater), if the samples collected and analyzed above the melt show no indication of an oxygen leak; or,

2. the cause of an elevated nitrogen level above the melt (as detected by port 1) in the absence of oxygen or water, might be identified as an air leak near the bottom of the crystal puller furnace, the oxygen being converted to carbon monoxide or silicon dioxide (which might also be detected by sampling at port 1, or alternatively might be swept out of the puller before being detected).

In any event, depending upon the level of the contaminant gas present, pulling may continue while the level is carefully watched and corrective action is taken. In this way, “trouble shooting” may be carried out while semiconductor growth continues. “Trouble shooting” can also be achieved, for example, by comparing the difference between the concentration of a particular contaminant gas at two different locations. In this way one can monitor for the presence of a difference, or an atypical difference, in the concentrations. One beneficial practice is to compare the levels of carbon monoxide present in samples collected at ports 2 and 3. Typically, any difference will be less than about 20 ppmv, 15 ppmv, 10 ppmv, 5 ppmv or even less than about 2 ppmv (with lower differences corresponding to lower “typical” levels of carbon monoxide present in the furnace; e.g., less than about 100 ppmv, 80 ppmv, 60 ppmv, 40 ppmv, 20 ppmv, or less). In this way, problems in the crystal puller, such as a blocked exhaust outlet, can be detected.

Carbon Content

Substitutional carbon, when present as an impurity in 5 single crystal silicon has the ability to catalyze the formation of oxygen precipitate nucleation centers. Accordingly, in some embodiments, the process of the present invention enables the close monitoring of the gaseous environment within the crystal puller, such that the carbon content of the semiconductor material that is formed has a low concentration of carbon; that is, the semiconductor material typically has a concentration of carbon which is less than about 5×10¹⁶ atoms/cm³, less than about 1×10¹⁶ atoms/cm³, or even less than about 5×10¹⁵ atoms/cm³.

### EXAMPLES

The following Examples set forth one approach that may be used to carry out the process of the present invention. Accordingly, these examples should not be interpreted in a limiting sense.

### Example 1

This example demonstrates the benefit of conducting an automated pre-fire check in accordance with the method of the present invention to test the vacuum integrity of the crystal puller prior to beginning the crystal growth process.

A crystal process development run was begun by loading a crucible with an initial charge of polysilicon and attaching a seed crystal to the crystal pulling system contained within a 300 mm Cz crystal growth furnace as described in FIGS. 1 and 2, such as that commercially available from Kayex of Rochester, N.Y. The furnace was closed and sealed and the furnace control system began the pre-fire vacuum check by closing the inert purge gas inlets and opening the main exhaust valve. The furnace was evacuated and placed under vacuum by pumping the air from within the crystal growth environment. When the pressure was reduced to about 200 mtorr, the main exhaust valve was closed, the purge inlet was opened and the furnace was filled with argon (Ar), to a pressure of about 100 torr. This cycle of reducing the pressure and then back-filling with an inert process gas was repeated two additional times. After the third cycle, the furnace was back-filled to a pressure of about 15 torr and the process gas inlets and main exhaust valves were balanced to provide for a flow rate of about 100 slm (standard liters per minute or liters per minute adjusted for standard temperature and pressure) through the pull chamber, the growth chamber and the exhaust piping. The gaseous environment within the crystal puller was monitored for about 10 minutes, with samples collected at a rate of one about every minute from Port 1, Port 2 and Port 3. The samples were then passed to a Qualitorr Orion Quadrupole Gas Mass Analyzer System (commercially available from the UTI Division of MKS from Walpole, Mass.) as the detector. Monitoring sample results are shown below in Table 1.

Referring to Table 1, samples taken from the crystal growth chamber (Port 1) and the LHS exhaust (Port 3) were well within the acceptable oxygen and nitrogen content ranges for automatic start-up of the furnace heater. However, monitoring results for N₂ and O₂ in the RHS exhaust (Port 2) were out of range for automatic starting. Because experience has shown it to be very unusual for the RHS and LHS exhaust samples to be different by more than about 10%, the crystal puller operator chose to abort the crystal production run and inspect the crystal growth chamber, wherein it was discovered that a plug of silicon oxide was lodged in the RHS Exhaust pipe. The plug was removed and the run restarted without incident. In this regard it should be noted, with respect to the water content levels, that as explained above these levels may be high in a crystal puller at ambient conditions. As a result, experience with a given puller may lead to the conclusion that levels in excess of 1000 ppmv are acceptable for start-up, because the levels are quickly reduced once the heaters are “fired” (the water quickly being vaporized and swept out of the crystal puller by the process purge gas flow).

TABLE 1
Pre-fire monitoring results.

| Sample | N₂ | N₂ | O₂ | O₂ | H₂O | H₂O |
|---|---|---|---|---|---|---|
| Port | (ppmv) | UCL | (ppmv) | UCL | (ppmv) | UCL |
| Port 1 | 50 | 100 | 14 | 30 | 623 | 200 |
| Port 2 | 70 | 50 | 17 | 10 | 1417 | 200 |
| Port 3 | 14 | 50 | 1 | 10 | 1181 | 200 |

Without monitoring the pre-fire vacuum check conditions with the method of the present invention, the plugged RHS exhaust pipe would not have been discovered prior to beginning the crystal growth process and the run would have commenced with the extreme likelihood of not producing any useable crystal. The plugged exhaust pipe would have caused the purge gases flowing through the growth chamber to be very unevenly distributed around the crystal. Most of the flow would be going to the left-hand side of the furnace. The usual consequences of such a condition is a build-up of oxide particles above the melt on the right-hand side. As the mass of small particles collects together and grows, larger particles will be created and many will become detached. Occasionally, one of these particles may be swept into the melt by gas currents created by the asymmetric flow of purge gas. A large particle of silicon oxide on the melt surface during crystal growth will generally become attached to the growing crystal and cause the loss of zero dislocation structure.

Additionally, an asymmetric flow of purge gases around the crystal will generally result in an increase in the carbon content of the crystal. This occurs because the asymmetric gas flow creates a lower pressure on the lower flow side of the growth chamber and by aspiration draws gases containing carbon monoxide (CO) from the lower portion of the growth chamber to the melt surface. The CO readily reacts with the liquid silicon and increases the carbon content of the melt.

### Example 2

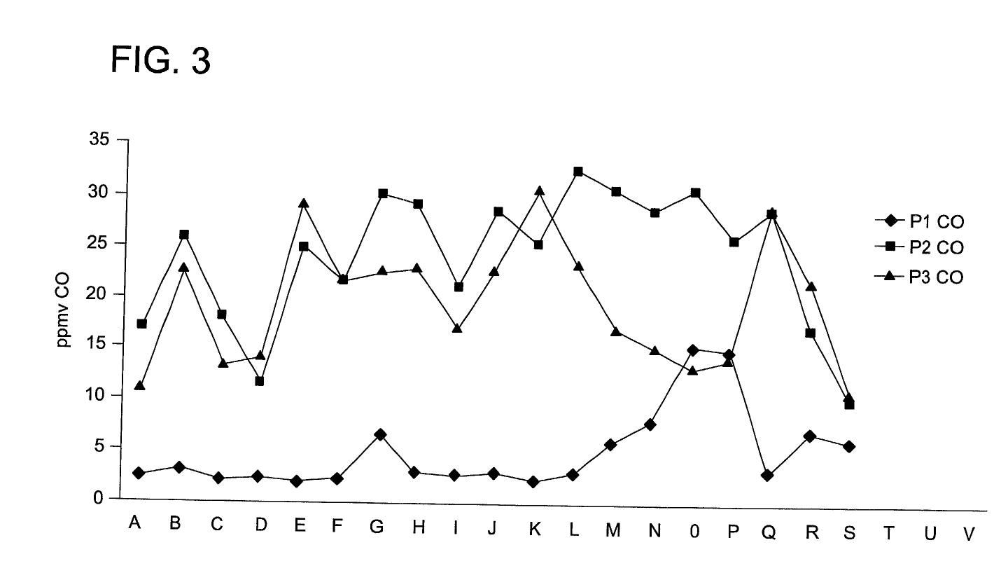

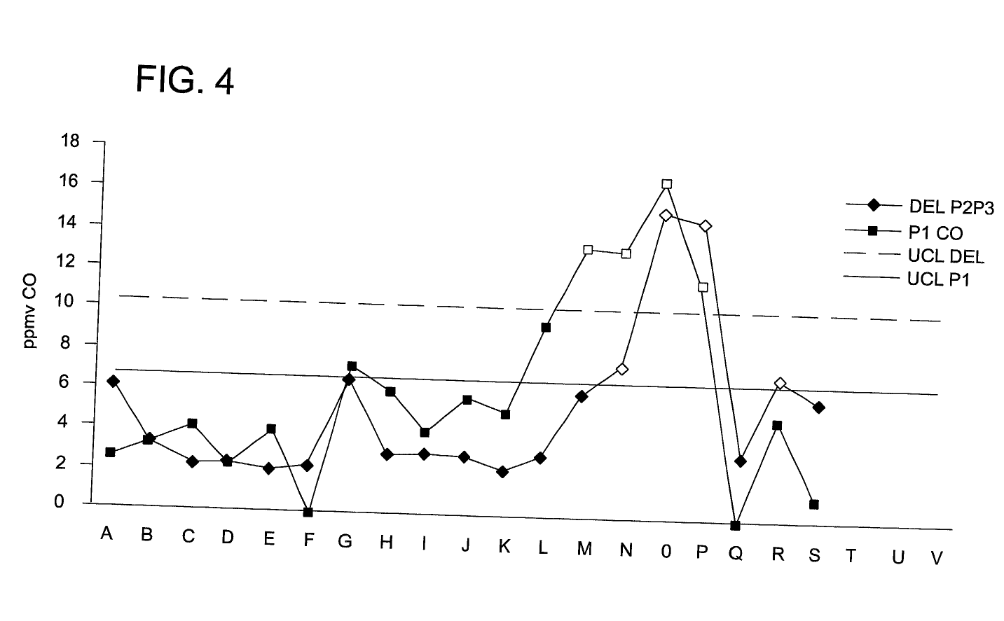

Nineteen single crystal silicon growth runs were completed in accordance with the Czochralski process using a 300 mm crystal growth furnace commercially available from Kayex of Rochester, N.Y. in order to demonstrate the utility and value of an automatic carbon monoxide (CO) monitoring and alarm system. The monitoring system was as described above and as shown in FIGS. 1 and 2 employing a Qualitorr Orion Quadrupole Gas Mass Analyzer System (RGA) (commercially available from the UTI Division of MKS, Walpole, Mass.). Samples were collected at intervals of one about every five minutes over the length of the main body of the ingots, based on the above described protocols. All of the collected data for each ingot was then averaged, to determine a single data point for each (as shown in FIGS. 3 and 4, further discussed below).

At the start of the experiment, the high CO alarm system was not yet automated; thus, the crystal puller operator was required to be vigilant in observing the gas composition displayed on the RGA video monitor. After 11 runs, indicated by runs labeled A through K on FIGS. 3 and 4, alarm limits (upper control limits or UCL) were set based upon the measured concentrations of CO above and adjacent to the melt at Port 1 (P1) and in the exhaust gases at Port 2 (P2) and Port 3 (P3). The alarm limits, as shown in FIGS. 3 and 4, were set for each port based upon control charting or statistical process control by setting the UCLs for each port at a value equal to the mean CO concentration observed in the first eleven runs plus three times the standard deviation observed in the same eleven runs.

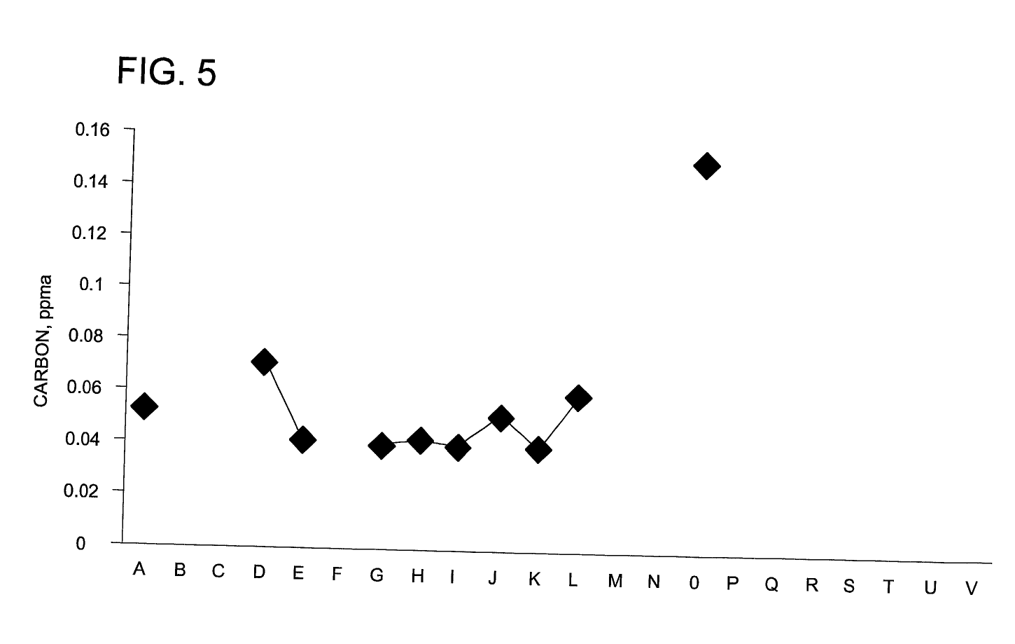

FIG. 4 graphically shows the difference in CO concentrations at P2 and P3 as compared to the CO concentrations at P1. The difference in CO at P2 and P3 is plotted in order to identify a condition of unbalanced purge flow through the crystal growth chamber and in particular around the crystal. After the first eleven runs, UCLs for the difference in CO concentration at P2 and P3 and the CO concentration at P1 were set. The UCLs were again calculated as the mean value of the first eleven runs plus three times the standard deviation associated with the same eleven runs. The results of FIG. 4 show that during body growth of the crystal in run M, the difference between the CO concentration at P2 and P3 exceeds the UCL. Since this was a first time occurrence, no corrective action was prescribed. However, during the runs after M, the difference between P2 and P3 CO concentration continued to increase. Also, starting with run N, the CO in the gas measured above the melt at P1 increased above the UCL. This is a condition that would be expected to cause the silicon melt to increase in carbon composition by reaction of CO in the gases at the melt surface with the molten silicon. To substantiate this, carbon measurements were obtained for the crystal from run O and several crystals from runs with CO below the UCL. As seen in FIG. 5, the carbon in crystal from run O was higher than in the other crystals.

The typical silicon crystal has a very shiny (highly reflective) surface when it is removed from the crystal growth furnace. Portions of the crystals produced between runs M and P had a flat (not reflective) gray surface.

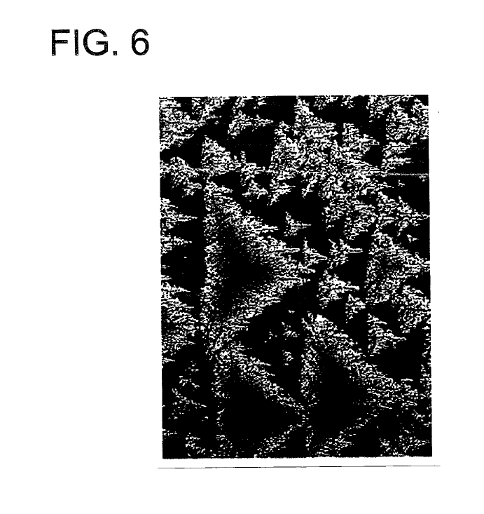

Photographs of the surface of the crystals from run E (low CO at Pi) and run N (high CO at Pi) and a microphotograph of the SiC crystallites formed on the surface of a crystal similar to the crystal from run N are given in FIG. 6.

The monitoring data from Run N suggested the flow of Argon in the RHS exhaust (P2) was constricted during the run causing an unbalance in the Ar purge around the crystal. The unbalanced purge was diluting the CO in the LHS exhaust stream monitored by P3. As a consequence of the unbalanced purge around the crystal, gases containing a high concentration of CO were being aspirated into the upper portion of the crystal growth furnace from the lower portion of the crystal growth furnace by the increased flow differential between the LHS exhaust pipe and the RHS exhaust pipe. Corrective action consisting of replacing the protective linings in the graphite upper sections of the exhaust pipes was taken before Run Q. As seen in FIGS. 3 and 4, the CO concentration at all three sampling ports was back to normal in Run Q and following. Carbon data available for Run S was found to be typical.

As experience is gained on out of control situations as represented by this example, corrective actions or preventive maintenance schemes can be developed to optimize process performance to improve crystal quality and reduce manufacturing costs.

### EXAMPLE 3

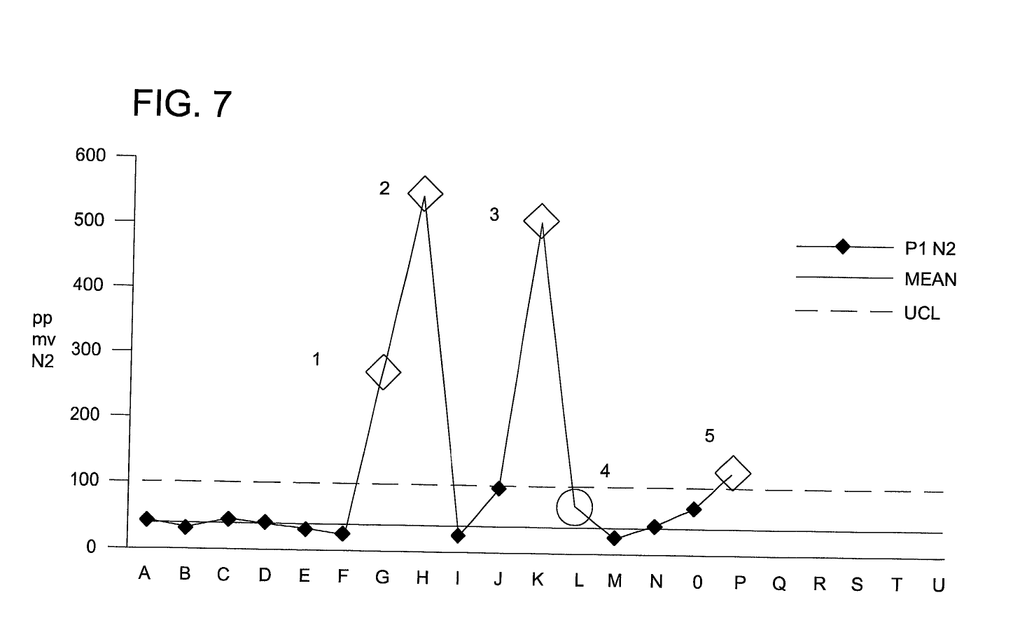

Sixteen crystal growth runs were conducted in accordance with the Czochralski process using a 300 mm crystal growth furnace commercially available from Kayex of Rochester, N.Y. in order to demonstrate the utility and value of an automatic monitoring and alarm system for detecting nitrogen and/or oxygen resulting from, for example, a leak. The monitoring system was as described above and as shown in FIGS. 1 and 2 employing a Qualitorr Orion Quadrupole Gas Mass Analyzer System (RGA) (commercially available from the UTI Division of MKS, Walpole, Mass.). Samples were collected at intervals of one about every five minutes during the growth process, based on the above described protocols. All of the collected data for each ingot was then averaged, to determine a single data point for each (as shown in FIGS. 7-10, further discussed below).

In this example, the alarm system was not yet automated; thus, the operator was required to be vigilant in observing the gas composition displayed on the RGA video monitor. After 11 runs, indicated by runs labeled A through K on FIGS. 7 through 10, alarm limits (upper control limits or UCL) were set based upon the measured concentrations of nitrogen above and adjacent to the melt at Port 1 (P1) and in the exhaust gases at Port 2 (P2) and Port 3 (P3). The alarm limits, as shown in FIGS. 7 through 10, were set for each port based upon control charting or statistical process control by setting the UCLs for each port at a value equal to the mean nitrogen concentration observed in the first eleven runs plus three times the standard deviation observed in the same eleven runs.

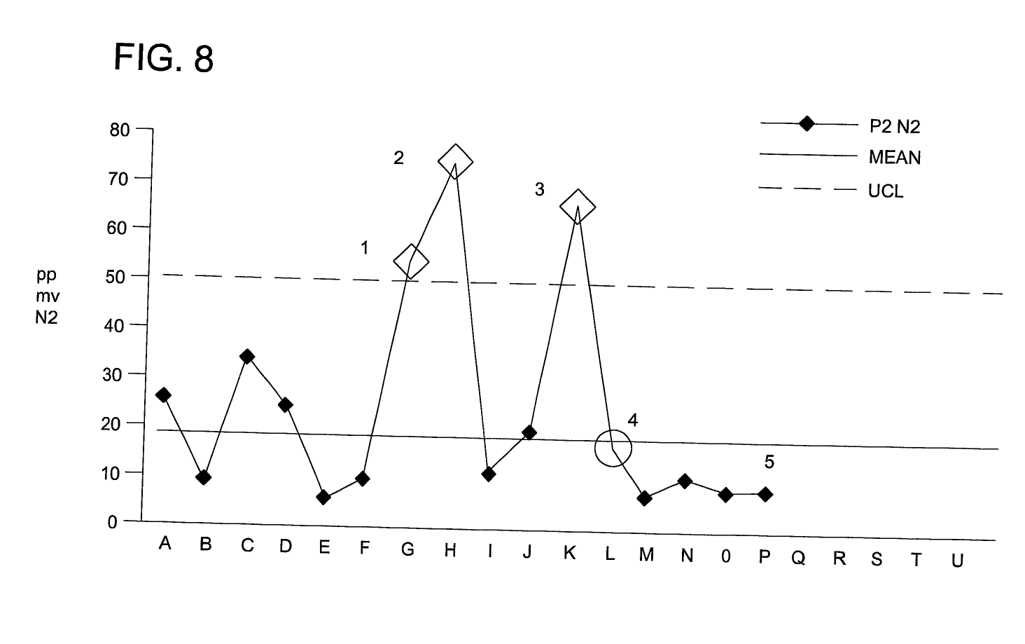

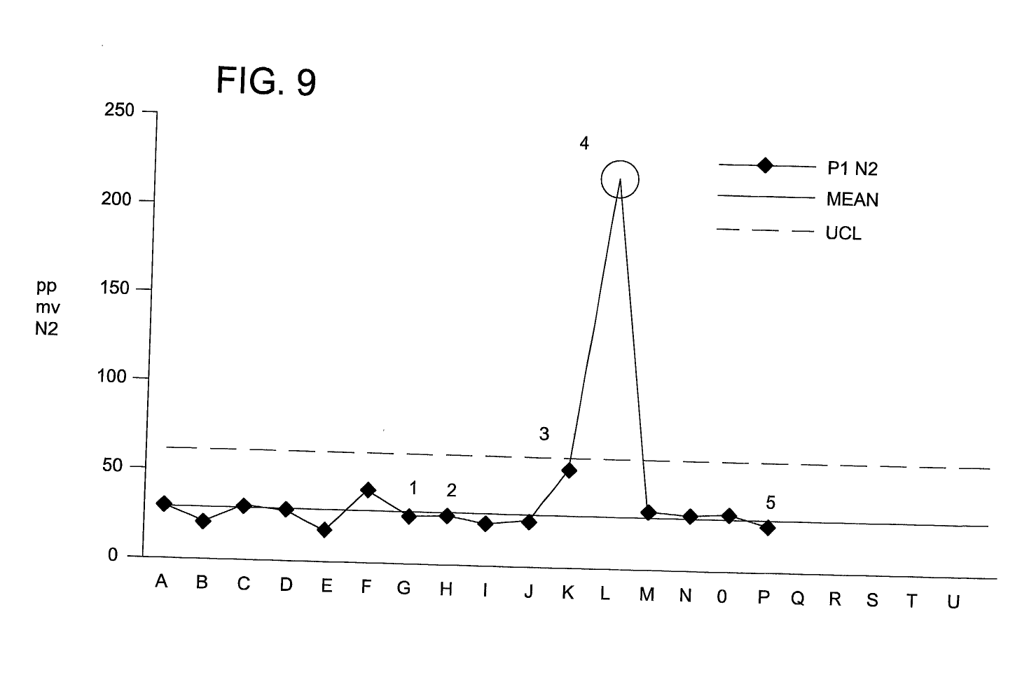

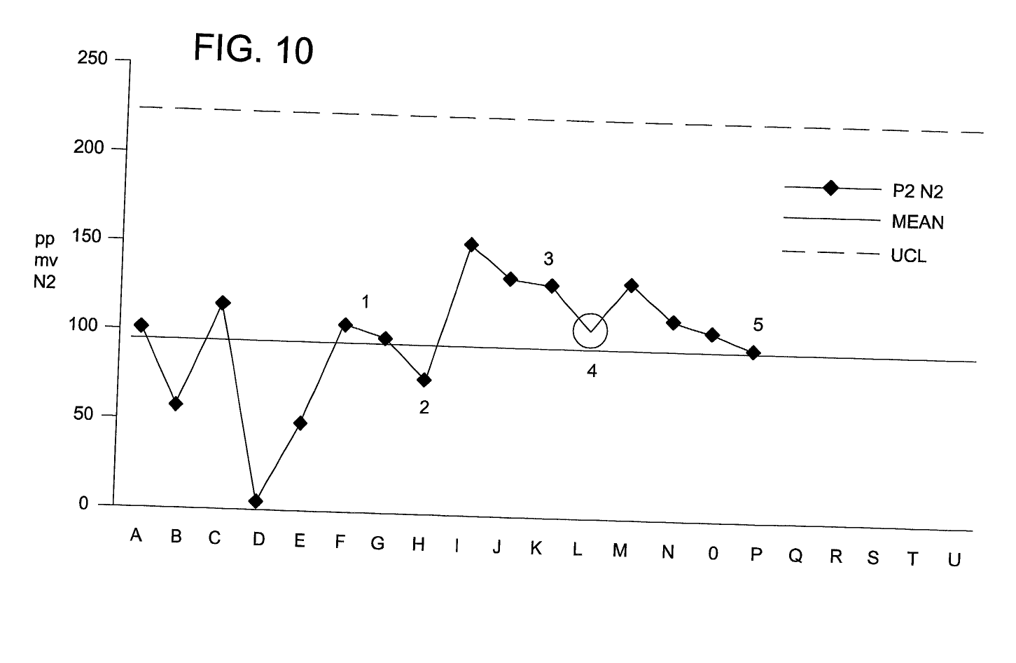

The runs were completed without incident until Run L. During Run L, the puller was leak tight at the pre-fire check as indicated at point number 4 in FIGS. 7 and 8. However, during the growth of the crystal, the operator noted that a leak was present during the body growth of the crystal. The leak was observed when Port 1 was monitored but not Port 2, as indicated at point number 4 in FIGS. 9 and 10. The level of N₂ was well above expectation at Port 1 but not above expectation at Port 2. Port 3 was also monitored but was identical to Port 2. The high concentration of N₂ at Port 1 but not at Port 2 indicated that the leak was near sampling port 1. It was suspected that the leak was in a granular poly feeding mechanism near port 1. An effort was made to stop the leak but was not successful. It was decided to allow the crystal cycle to continue to determine the effect on zero defect growth of a leak of this magnitude. It was quickly decided that zero defect crystal could not be produced due to the leak and the cycle was terminated.

In three crystal growth cycles prior to L and one following L, N₂ was noted to be above expectation during the pre-fire check with the RGA (see points 1, 2, 3 and 5 in FIGS. 7 and 8). Corrective action was taken before crystal growth, and as a result of the corrective action, no leak was observed during crystal growth as indicated by points 1, 2, 3, and 5 in FIGS. 9 and 10.

Without monitoring the gases at Port 1 with the RGA, an air leak would not have been identified as the cause of the failed crystal growth cycle. In this case, the information on the leak from the RGA and the failure to grow a zero defect crystal, led to the decision to shorten the cycle and save valuable time which was used to begin the next cycle.

In view of the above, it will be seen that the several objects of the invention are achieved. As various changes could be made in the above material and processes without departing from the scope of the invention, it is intended that all matter contained in the above description be interpreted as illustrative and not in a limiting sense.

What is claimed is:

1. A process for monitoring the gaseous environment in a crystal pulling furnace, used for the growth of an ingot of semiconductor material in a growth chamber maintained at a sub-atmospheric pressure, the process comprising:
sealing the growth chamber;
reducing the pressure within the sealed chamber to a sub-atmospheric level;
introducing a process gas into the chamber to purge the chamber and form a gaseous environment within the chamber; and,
analyzing the gaseous environment for a contaminant gas in a concentration in excess of the concentration of said gas in the process gas.

2. A process as set forth in claim 1 wherein the contaminant gas is selected from the group consisting of nitrogen, oxygen, carbon monoxide and water vapor.

3. A process as set forth in claim 1 wherein the concentration of the contaminant gas for which analysis is performed is reported in real time.

4. A process as set forth in claim 1 wherein a residual gas mass analyzer or a gas chromatograph is used to analyze the gaseous environment.

5. A process as set forth in claim 1 wherein the ingot has a nominal diameter of at least about 150 mm, 200 mm, 300 mm or more.

6. A process as set forth claim 1 wherein the ingot has a carbon concentration of less than about 5×10¹⁶ atoms/cm³, 1×10¹⁶ atoms/cm³, or even 5×10¹⁵ atoms/cm³.

7. A process as set forth in claim 1 wherein a mass of molten semiconductor material is formed in the growth chamber, the analysis being performed prior to the formation of the molten mass.

8. A process as set forth in claim 7 wherein the gaseous environment is analyzed to determine if the concentration of nitrogen is less than about 600 ppmv, 400 ppmv, 200 ppmv or 100 ppmv, prior to formation of the molten mass.

9. A process as set forth in claim 8 wherein the gaseous environment is analyzed about once every 20 minutes, 15 minutes, 10 minutes, 5 minutes, 1 minute or less.

10. A process as set forth in claim 8 wherein the gaseous environment is continuously analyzed.

11. A process as set forth in claim 8 wherein the gaseous environment is analyzed by collecting a sample of a gaseous atmosphere above or adjacent to a melt surface of the molten mass formed in the growth chamber.

12. A process as set forth in claim 8 wherein the gaseous environment is analyzed by collecting a sample of an exhaust gas from the sealed growth chamber.

13. A process as set forth in claim 7 wherein the gaseous environment is analyzed to determine if the concentration of oxygen is less than about 100 ppmv, 90 ppmv, 60 ppmv, or 30 ppmv, prior to the formation of the molten mass.

14. A process as set forth in claim 13 wherein the gaseous environment is analyzed about once every 20 minutes, 15 minutes, 10 minutes, 5 minutes, 1 minute or less.

15. A process as set forth in claim 13 wherein the gaseous environment is continuously analyzed.

16. A process as set forth in claim 13 wherein the gaseous environment is analyzed by collecting a sample of a gaseous atmosphere above or adjacent to a melt surface of the molten mass formed in the growth chamber.

17. A process as set forth in claim 13 wherein the gaseous environment is analyzed by collecting a sample of an exhaust gas from the sealed growth chamber.

18. A process as set forth in claim 7 wherein the gaseous environment is analyzed to determine if the concentration of water vapor is less than about 1000 ppmv, 800 ppmv, 400 ppmv, or 200 ppmv, prior to the formation of the molten mass.

19. A process as set forth in claim 18 wherein the gaseous environment is analyzed about once every 20 minutes, 15 minutes, 10 minutes, 5 minutes, 1 minute or less.

20. A process as set forth in claim 18 wherein the gaseous environment is continuously analyzed.

21. A process as set forth in claim 18 wherein the gaseous environment is analyzed by collecting a sample of a gaseous atmosphere above or adjacent to a melt surface of the molten mass formed in the growth chamber.

22. A process as set forth in claim 18 wherein the gaseous environment is analyzed by collecting a sample of an exhaust gas from the sealed growth chamber.

23. A process as set forth in claim 7 wherein a mass of m olten semiconductor material is formed and an ingot is grown from the molten mass formed in the growth chamber, the analysis being performed during ingot growth.

24. A process as set forth in claim 23 wherein the gaseous environment is analyzed by collecting a sample of a gaseous atmosphere above or adjacent to a melt surface of the molten mass formed in the growth chamber.

25. A process as set forth in claim 24 wherein the gaseous environment is analyzed to determine if the concentration of nitrogen is less than about 600 ppmv, 400 ppmv, 200 ppmv or 100 ppmv.

26. A process as set forth in claim 24 wherein the gaseous environment is analyzed to determine if the concentration of oxygen is less than about 100 ppmv, 90 ppmv, 60 ppmv, or 30 ppmv.

27. A process as set forth in claim 24 wherein the gaseous environment is analyzed to determine if the concentration of water vapor is less than about 1000 ppmv, 800 ppmv, 400 ppmv, or 200 ppmv.

28. A process as set forth in claim 24 wherein the gaseous environment is analyzed to determine if the concentration of carbon monoxide is less than about 30 ppmv, 20 ppmv, 10 ppmv or 5 ppmv.

29. A process as set forth in claim 24 wherein the gaseous environment is analyzed about once every 20 minutes, 15 minutes, 10 minutes, 5 minutes, 1 minute or less.

30. A process as set forth in claim 24 wherein the gaseous environment is continuously analyzed.

31. A process as set forth in claim 24 wherein the concentration of the contaminant gas for which analysis is performed is reported in real time.

32. A process as set forth in claim 24 wherein a residual gas mass analyzer or a gas chromatograph is used to analyze the gaseous environment.

33. A process as set forth in claim 24 wherein the ingot has a nominal diameter of at least about 150 mm, 200 mm, 300 mm or more.

34. A process as set forth claim 24 wherein the ingot has a carbon concentration of less than about 5×10¹⁶ atoms/cm³, 1×10¹⁶ atoms/cm³, or even 5×10¹⁵ atoms/cm³.

35. A process as set forth in claim 23 wherein the gaseous environment is analyzed by collecting a sample of an exhaust gas from the sealed growth chamber.

36. A process as set forth in claim 35 wherein the gaseous environment is analyzed to determine if the concentration of nitrogen is less than about 600 ppmv, 400 ppmv, 200 ppmv or 100 ppmv.

37. A process as set forth in claim 35 wherein the gaseous environment is analyzed to determine if the concentration of oxygen is less than about 100 ppmv, 90 ppmv, 60 ppmv, or 30 ppmv.

38. A process as set forth in claim 35 wherein the gaseous environment is analyzed to determine if the concentration of water vapor is less than about 1000 ppmv, 800 ppmv, 400 ppmv, or 200 ppmv.

39. A process as set forth in claim 35 wherein the gaseous environment is analyzed to determine if the concentration of carbon monoxide is less than about 100 ppmv, 80 ppmv, 60 ppmv, 40 ppmv, or 20 ppmv.

40. A process as set forth in claim 35 wherein the gaseous environment is analyzed about once every 20 minutes, 15 minutes, 10 minutes, 5 minutes, 1 minute or less.

41. A process as set forth in claim 35 wherein the gaseous environment is continuously analyzed.

42. A process as set forth in claim 35 wherein the concentration of the contaminant gas for which analysis is performed is reported in real time.

43. A process as set forth in claim 35 wherein a residual gas mass analyzer or a gas chromatograph is used to analyze the gaseous environment.

44. A process as set forth in claim 35 wherein the ingot has a nominal diameter of at least about 150 mm, 200 mm, 300 mm or more.

45. A process as set forth claim 35 wherein the ingot has a carbon concentration of less than about 5×10¹⁶ atoms/cm³, 1×10¹⁶ atoms/cm³, or even 5×10¹⁵ atoms/cm³.

46. A process as set forth in claim 23 wherein the analysis is performed during one or more of the following steps in the growth process: formation of a molten mass, growth of a neck portion of an ingot, growth of a seed-cone of an ingot, growth of about 20%, 40%, 60%, 80% or about all of a main body of an ingot, and growth of an end-cone of an ingot.

47. A process as set forth in claim 23 wherein the analysis is initiated when growth of the main body of the ingot begins, and wherein the analysis continues until growth of an end-cone begins.

48. A process as set forth in claim 23 wherein the analysis is performed during growth of about the first half of the main body of said ingot.

49. A process as set forth in claim 23 wherein the analysis is performed during growth of about the second half of the main body of said ingot.

50. A process as set forth in claim 23 wherein the analysis is initiated when the silicon molten melt begins to form, and wherein the analysis continues until cooling of the growth chamber begins.

51. A system for use in combination with an apparatus for growing a semiconductor ingot, said semiconductor growing apparatus having a growth chamber which is maintained at a sub-atmospheric pressure and which contains a gaseous environment comprising a process purge gas, said system comprising:
a port for withdrawing a sample of the gaseous environment from the growth chamber;
a detector for analyzing the sample for a contaminant gas in a concentration in excess of the concentration of said gas in the process purge gas and generating a signal representative of the detected concentration of the contaminant gas, said detector receiving the sample from the growth chamber via a conduit connected to the port; and,
a control circuit receiving and responsive to the signal generated by the detector for determining if the detected concentration of the contaminant gas exceeds a pre-set threshold concentration for said contaminant gas, said control circuit controlling the semiconductor growth apparatus in response to the determination.

52. The system of claim 51 further comprising an alarm responsive to said control circuit for indicating if the detected concentration of the contaminant gas is in excess of the threshold concentration.

53. A process for use in combination with an apparatus for growing a semiconductor ingot, said growing apparatus having a growth chamber which is maintained at a sub-atmospheric pressure and which contains a gaseous environment comprising a process purge gas, the process comprising:
transferring a sample of the gaseous environment from the growth chamber via a conduit to a detector for analyzing said sample;
analyzing said sample to determine if a contaminant gas is present in a concentration in excess of the concentration of said contaminant gas in the process gas;
determining at least one parameter representative of a condition of the growth process based on the determination of whether the contaminant gas concentration in the sample exceeds the concentration in the process gas; and,
controlling the semiconductor growing apparatus in response to the determined parameter.
